(19) United States
(12) Patent Application Publication
(10) Pub. No.: US 2010/0058984 A1
(43) Pub. Date: Mar. 11, 2010

(54) Substrate Processing Apparatus

(76) Inventors: Tetsuya Marubayashi, Toyama-shi (JP); Atsushi Moriya, Toyama-shi (JP)

Correspondence Address: North Star Intellectual Property Law, PC, P.O. Box 34688, Washington DC, DC, 20043, US

(21) Appl. No.: 12/553,143

(22) Filed: Sep. 3, 2009

(30) Foreign Application Priority Data
Sep. 10, 2008 (JP) 2008-232618

(51) Int. Cl. C23C 16/00

(52) U.S. Cl. 118/715

(57) ABSTRACT

Process gas discharged from a bypass pipe to a gas exhaust system can be prevented from diffusing back to the inside of a process chamber without having to install a dedicated vacuum pump at the downstream side of the bypass pipe. The substrate processing apparatus includes a process chamber accommodating a substrate, a gas supply system supplying process gas from a process gas source to the process chamber for processing the substrate, a gas exhaust system configured to exhaust the process chamber, two or more vacuum pumps installed in series at the gas exhaust system, and a bypass pipe connected between the gas supply system and the gas exhaust system. The most upstream one of the vacuum pumps is a mechanical booster pump, and the bypass pipe is connected between the mechanical booster pump and the rest vacuum pumps located at a downstream side of the mechanical booster pump.

### CROSS-REFERENCE TO RELATED PATENT APPLICATION

This U.S. non-provisional patent application claims priority under 35 U.S.C. §119 of Japanese Patent Application No. 2008-232618, filed on Sep. 10, 2008, in the Japanese Patent Office, the entire contents of which are hereby incorporated by reference.

### BACKGROUND OF THE INVENTION

1. Field of the Invention

The present invention relates to a substrate processing apparatus configured to process a substrate.

2. Description of the Prior Art

Films such as an epitaxial silicon film (Epi-Si film) and an epitaxial silicon germanium film (Epi-SiGe film) can be grown on a substrate by supplying process gas to the inside of a process chamber in which the substrate is accommodated. For growing an epitaxial film, it may be necessary to stabilize the flowrate of process gas supplied to the inside of the process chamber. For this end, prior to the supply of process gas to the inside of the process chamber, the inside of the process chamber is exhausted through a bypass pipe installed at a gas supply system to stabilize the flowrate of process gas supplied from the gas supply system.

In a substrate processing apparatus of the related art, the downstream side of a bypass pipe is connected to the upstream side of a vacuum pump installed at an exhaust system configured to exhaust the inside of a process chamber. For example, the vacuum pump of the exhaust system includes a mechanical booster pump and a dry pump that are sequentially installed from the upstream side. For example, the vacuum pump may have 30000-slm exhaustion ability.

However, when process gas is exhausted through the bypass pipe, process gas flowing from the bypass pipe to the gas exhaust system can be momentarily diffused back to the inside of the process chamber (back-diffusion or backflow). In this case, substances such as contaminants remaining in the gas exhaust system may permeate into the process chamber together with the process gas, and thus the substrate processing quality or process yield may be decreased. To prevent back diffusion to the inside of the process chamber, a dedicated vacuum pump can be installed at the downstream side of the bypass pipe instead of connecting the downstream side of the bypass pipe to the gas exhaust system. However, this may complicate the structure of the substrate processing apparatus and increase the manufacturing costs and installation space (footprint) of the substrate processing apparatus.

### SUMMARY OF THE INVENTION

An object of the present invention is to provide a substrate processing apparatus configured so that process gas exhausted through a bypass pipe to a gas exhaust system can be restrained from diffusing back to the inside of a process chamber without having to install a dedicated vacuum pump at the downstream side of the bypass pipe.

According to an aspect of the present invention, there is provided a substrate processing apparatus including: a process chamber configured to accommodate a substrate; a gas supply system configured to supply a process gas from a process gas source to an inside of the process chamber for processing the substrate; a gas exhaust system configured to exhaust an inside atmosphere of the process chamber; two or more vacuum pumps installed in series at the gas exhaust system; and a bypass pipe connected between the gas supply system and the gas exhaust system for bypassing the process chamber, wherein the most upstream vacuum pump of the vacuum pumps installed at the gas exhaust system is a mechanical booster pump, and the bypass pipe is connected between the mechanical booster pump and the rest vacuum pumps located at a downstream side of the mechanical booster pump.

### BRIEF DESCRIPTION OF THE DRAWINGS

FIG. 1 is a schematic view illustrating a substrate processing apparatus according to an embodiment of the present invention.

FIG. 2 is a schematic view illustrating a process furnace of the substrate processing apparatus according to an embodiment of the present invention.

FIG. 3 is a schematic view illustrating a gas supply system, a bypass pipe, and a gas exhaust system of the substrate processing apparatus according to an embodiment of the present invention.

FIG. 4 is a schematic view illustrating modified structures of the bypass pipe and the gas exhaust system of FIG. 3.

FIG. 5 is a schematic view illustrating a gas supply system, a bypass pipe, and a gas exhaust system of a substrate processing apparatus of the related art.

FIG. 6 is a schematic view illustrating modified structures of the bypass pipe and the gas exhaust system of FIG. 5.

FIG. 7 is a schematic view illustrating a gas supply system, a bypass pipe, and a gas exhaust system of a substrate processing apparatus of the related art, in which a dedicated pump is installed at the bypass pipe.

FIG. 8 is a schematic view illustrating modified structures of the bypass pipe and the gas exhaust system of FIG. 7.

FIG. 9 is a flowchart for explaining a substrate processing process according to an embodiment of the present invention.

### DETAILED DESCRIPTION OF THE PREFERRED EMBODIMENTS

An epitaxial silicon film (Epi-Si film) or an epitaxial silicon germanium film (Epi-SiGe film) can be grown on a substrate by supplying process gas to the inside of a process chamber in which the substrate is accommodated. For growing an epitaxial film, it may be necessary to maintain the flowrate of process gas more stably as compared with the case of growing a polysilicon film (Poly-Si film).

For example, in the case of growing an Epi-SiGe film on a silicon substrate, silane-based gas such as SiH₄ gas and Si₂H₆ gas, and germanium-based gas such as GeH₄ gas, or chlorine-based gas such as Cl₂ gas are sequentially or simultaneously supplied to the inside of a process chamber, and it is necessary to stabilize the flowrates of gases supplied to the inside of the process chamber so as to control the ratio of silicon (Si) and germanium (Ge) precisely. In addition, gas such as B₂H₆ gas diluted with H₂ gas may be supplied the inside of the process chamber to dope the Epi-SiGe film with a predetermined amount of boron (B), and in this case, it may also be necessary to stabilize the flowrates of gases supplied to the inside of the process chamber so as to precisely control the amount of boron (B) doped into the Epi-SiGe film. Furthermore, an Epi-Si film can be grown by repeating a process of supplying Cl₂ gas to the inside of the process chamber for a short time (for example, 30 seconds) after supplying silane-based gas such as SiH₄ gas or Si₂H₆ gas to the inside of the process chamber, and in this case, it may also be necessary to stabilize the flowrate of Cl₂ gas supplied to the inside of the process chamber.

As a way of stabilizing the flowrate of process gas, it is effective to exhaust process gas from the inside of the process chamber through a bypass pipe installed at a gas supply system prior to the supply of process gas to the inside of the process chamber. By exhausting process gas through the bypass pipe, undesired phenomena such as an initial overshoot of the flowrate of process gas supplied through the gas supply system can be prevented. By starting supply of process gas to the inside of the process chamber after preventing such an overshoot, the flowrate of process gas supplied to the inside of the process chamber can be stabilized.

However, according to studies carried out by the inventors et al, in the case where process gas is exhausted through a bypass pipe in a substrate processing apparatus of the related art, process gas exhausted through the bypass pipe to a gas exhaust system can be momentarily diffused back to the inside of the process chamber (back-diffusion or backflow) instead of flowing to the downstream side of the gas exhaust system. Therefore, the inventors et al. have carried out research on a method of preventing back-diffusion of process gas, and as a result, it has been found that the above-mentioned problems can be solved by improving a connection point of the bypass pipe to the downstream side.

### An Embodiment of the Present Invention

Hereinafter, based on the above-mentioned knowledge, an embodiment of the present invention will be described.

(1) Structure of Substrate Processing Apparatus

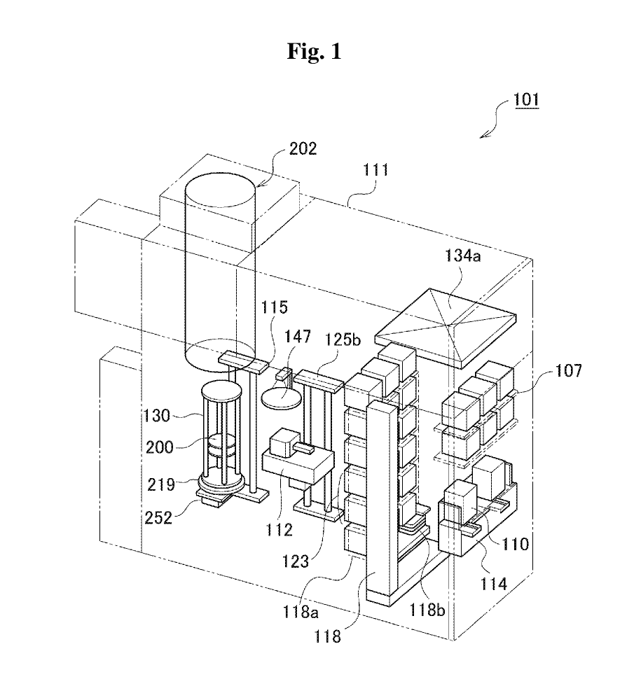

First, a substrate processing apparatus will be described with reference to FIG. 1 according to an embodiment of the present invention.

As shown in FIG. 1, a substrate processing apparatus 101 relevant to the current embodiment includes a housing 111. At the front inner side (right side in FIG. 1) of the housing 111, a cassette stage 114 is installed. Between the cassette stage 114 and an external carrying device (not shown), cassettes (pods) 110 used as substrate containers are transferred. At the rear side of the cassette stage 114, a cassette elevator 118 is installed as a lifting unit for moving a cassette 110 upward and downward. At the cassette elevator 118, a cassette transfer machine 118b is installed as a carrying unit capable of moving a cassette 110 horizontally. In addition, at the rear side of the cassette elevator 118, a cassette self 118a is installed as a stage for placing cassettes 110. At the cassette self 118a, a transfer self 123 is installed. At the transfer self 123, cassettes 110 accommodating unprocessed or processed substrates are temporarily placed. In addition, at the upper side of the cassette stage 114, an auxiliary cassette self 107 is installed as a stage for placing cassettes 110. At the upside of the auxiliary cassette self 107, a cleaning unit 134a is installed to supply clean air to the inside of the housing 111.

At the upper side of the rear region (left in FIG. 1) of the housing 111, a cylindrical process furnace 202 having an opened bottom side is vertically installed. The structure of the process furnace 202 will be described later in detail.

At the lower side of the process furnace 202, a boat elevator 115 is installed as a lifting unit. At the lower end part of the boat elevator 115, a lift base plate 252 is installed. On the lift base plate 252, a boat 130 used as a substrate holding unit is vertically mounted in a state where a seal cap 219 is disposed between the lift base plate 252 and the boat 130 as a cover body. The structures of the boat elevator 115 and the boat 130 will be described later in detail. If the boat elevator 115 is moved upward, the boat 130 is loaded into the process furnace 202, and at the same time, the bottom side of the process furnace 202 is air-tightly sealed by the seal cap 219. In addition, beside the bottom side of the process furnace 202, a furnace shutter 147 is installed as a closing unit. When the boat elevator 115 is moved downward, the furnace shutter 147 is used to air-tightly close the bottom side of the process furnace 202.

Between the process furnace 202 and the cassette self 118a, a transfer elevator 125b is installed as a lifting unit for lifting and moving a wafer 200. At the transfer elevator 125b, a wafer transfer machine 112 is mounted as a carrying unit for horizontally moving a wafer 200.

(2) Operation of Substrate Processing Apparatus

Next, operations of the substrate processing apparatus relevant to the current embodiment will be described with reference to FIG. 1.

First, a cassette 110 charged with wafers 200 is carried to the cassette stage 114 by the external carrying device (not shown). At this time, the cassette 110 is placed in a manner such that the wafers 200 are vertically positioned. Thereafter, the cassette stage 114 is rotated by 90°, and thus the surfaces of the wafers 200 are horizontally positioned to face the top side of the substrate processing apparatus (that is, upside in FIG. 1).

After that, vertical and horizontal operations of the cassette elevator 118 are associated with forward/backward and rotatory operations of the cassette transfer machine 118b so as to carry the cassette 110 to the cassette self 118a or the auxiliary cassette self 107. Thereafter, the cassette 110 used to transfer wafers 200 is transferred to the transfer self 123 by associating operations of the cassette elevator 118 and the cassette transfer machine 118b.

Thereafter, by associating forward/backward and rotatory operations of the wafer transfer machine 112 with the lifting operation of the transfer elevator 125b, the wafers 200 charged in the cassette 110 placed on the transfer self 123 can be transferred (charged) into the boat 130 that is in a lower position.

After that, the boat elevator 115 is elevated, so that the boat 130 can be loaded into the process furnace 202, and at the same time, the inside of the process furnace 202 can be air-tightly sealed by the seal cap 219. Then, the wafers 200 are heated in the process furnace 202 which is air-tightly sealed and depressurized, and process gas is supplied to the inside of the process furnace 202, so as to process the surfaces of the wafers 200. Such a processing process will be described later in detail.

After the wafers 200 are processed, the wafers 200 are transferred from the inside of the boat 130 to the cassette 110 placed on the transfer self 123 in a reverse order to the above-described order. Then, the cassette 110 accommodating the processed wafers 200 is transferred from the transfer self 123 to the cassette stage 114 by the cassette transfer machine 118b and is carried to the outside of the housing 111 by the external carrying device (not shown). After the boat elevator 115 is moved downward, the bottom side of the process furnace 202 is air-tightly closed by the furnace shutter 147 so as to prevent permeation of external air into the process furnace 202.

(3) Structure of Process Furnace

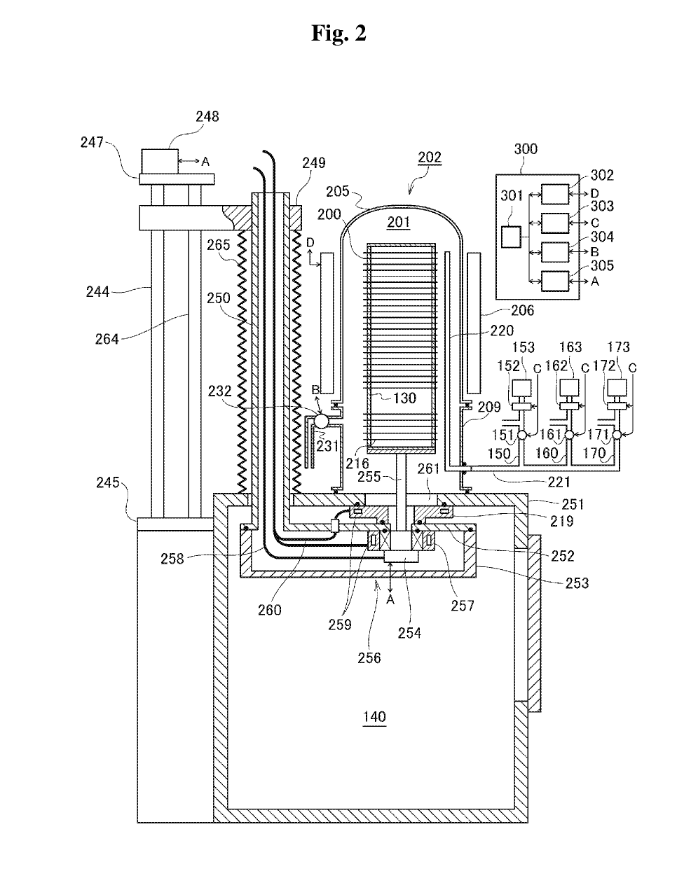

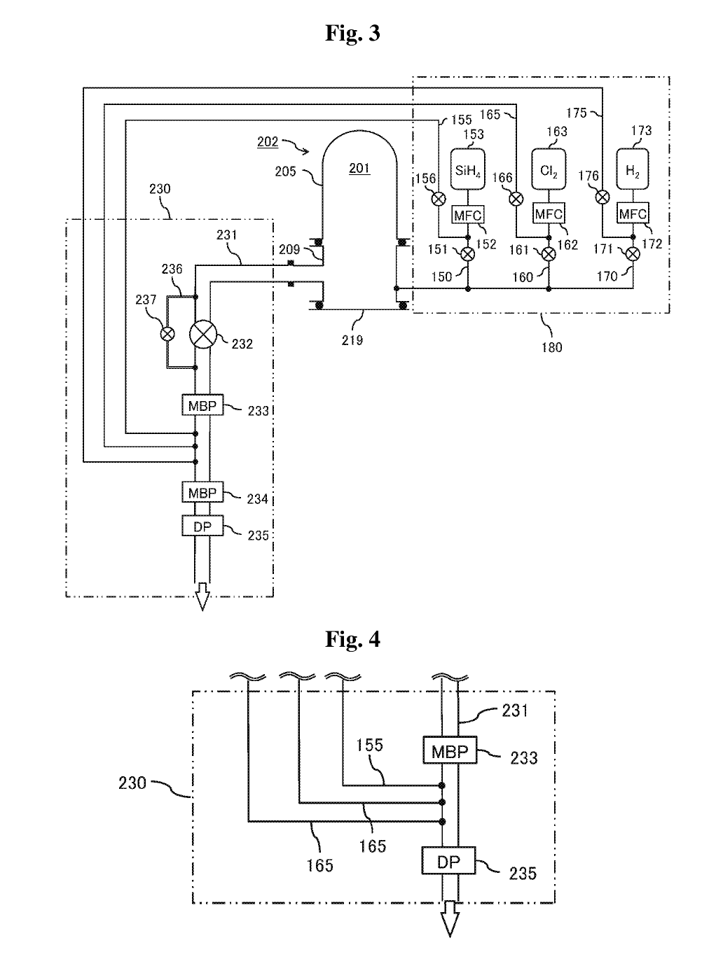

Next, with reference to FIG. 2 to FIG. 4, explanations will be given on the process furnace 202 of the substrate processing apparatus relevant to the current embodiment and surrounding structures of the process furnace 202. FIG. 2 is a schematic view illustrating the process furnace of the substrate processing apparatus relevant to an embodiment of the present invention. FIG. 3 is a schematic view illustrating a gas supply system, a bypass pipe, and a gas exhaust system of the substrate processing apparatus relevant to an embodiment of the present invention. FIG. 4 is a schematic view illustrating modified structures of the bypass pipe and the gas exhaust system illustrated in FIG. 3.

(Process Chamber)

As shown in FIG. 2, the process furnace 202 relevant to the current embodiment includes an outer tube 205 as a reaction tube. The outer tube 205 is made of a heat-resistant material such as quartz (SiO₂) or silicon carbide (SiC) and has a cylindrical shape with a closed top side and an opened bottom side. In a cylindrical hollow inner part of the outer tube 205, a process chamber 201 is formed for processing substrates such as wafers 200 in a depressurized condition. The process chamber 201 is configured to accommodate substrates such as wafers 200 in a state where the wafers 200 are horizontally positioned and vertically arranged in multiple stages in the boat 130 (described later in detail). The present invention is not limited to the case where a plurality of wafers 200 are accommodated in the process chamber 201. For example, the present invention can be properly applied to the case where only a single wafer 200 is accommodated in the process chamber 201.

At the outside of the outer tube 205, a heater 206 used as a heating device is installed coaxially with the outer tube 205. The heater 206 has a cylindrical shape. The heater 206 includes a heater wire and an insulating material installed around the heater wire. The heater 206 is vertically installed in a manner such that the heater 206 is supported on a holding body (not shown). Near the heater 206, a temperature sensor (not shown) is installed as a temperature detector for detecting the inside temperature of the process chamber 201. A temperature control unit 302 is electrically connected to the heater 206 and the temperature sensor. Based on temperature information detected by the temperature sensor, the temperature control unit 302 adjusts power supplied to the heater 206 so as to maintain the process chamber 201 at a desired temperature distribution at a desired time.

At the lower side of the outer tube 205, a manifold 209 is installed coaxially with the outer tube 205. The manifold 209 is made of a material such as stainless steel and has a cylindrical shape with opened top and bottom sides. The manifold 209 is installed to support the outer tube 205. Between the manifold 209 and the outer tube 205, an O-ring is installed as a seal member. In addition, at the lower side of the manifold 209, a loadlock chamber 140 is installed as an auxiliary chamber. Between the manifold 209 and a top plate 251 of the loadlock chamber 140, an O-ring is installed as a seal member. The manifold 209 is supported by the top plate 251 such that the outer tube 205 can be vertically installed. The outer tube 205 and the manifold 209 constitute a reaction vessel. A furnace port 261 is formed in the top plate 251 as an opening of the process furnace 202.

(Gas Supply System)

As shown in FIG. 2, united as one pipe and connected to the sidewall of the manifold 209 are: a first gas supply pipe 150 used as a first gas supply system configured to supply a first process gas to the inside of the process chamber 201 for processing wafers 200; a second gas supply pipe 160 used as a second gas supply system configured to supply a second process gas to the inside of the process chamber 201 for processing wafers 200; and a third gas supply pipe 170 used as a third gas supply system configured to supply a third process gas to the inside of the process chamber 201 for processing wafers 200 are united as one and connected to the sidewall of the manifold 209. A gas supply nozzle 220 configured to supply process gas to the inside of the process chamber 201 is connected to the downstream side of the pipe to which the first gas supply pipe 150, the second gas supply pipe 160, and the third gas supply pipe 170 are united. The gas supply nozzle 220 is vertically installed along the inner wall of the process chamber 201. Gas supply holes are formed in the gas supply nozzle 220 so that process gas can be supplied to gaps between stacked wafers 200. However, the gas supply nozzle 220 is not limited to the above-described structure. For example, a plurality of branch nozzles having different heights may branch off from the downstream side of the gas supply nozzle 220. In this case, each of the branch nozzles may not include gas supply holes but be configured so that process gas is supplied through a downstream-side end part of the branch nozzle in an upward direction.

From the upstream side of the first gas supply pipe 150, a first process gas supply source 153 configured to supply a first process gas, a mass flow controller (MFC) 152 used as a flowrate control unit, and a valve 151 are sequentially installed in series. From the upstream side of the second gas supply pipe 160, a second process gas supply source 163 configured to supply a second process gas, an MFC 162 used as a flowrate control unit, and a valve 161 are sequentially installed in series. From the upstream side of the third gas supply pipe 170, a third process gas supply source 173 configured to supply a third process gas, an MFC 172 used as a flowrate control unit, and a valve 171 are sequentially installed in series. The first process gas supply source 153 is configured to supply a first process gas: for example, silane-based gas such as flammable SiH₄ gas or Si₂H₆ gas, or germanium-based gas such as GeH₄ gas. The second process gas supply source 163 is configured to supply a second process gas such as Cl₂ gas which increases the susceptibility of substances to burn. The third process gas supply source 173 is configured to supply a third process gas such as H₂ gas.

The gas supply system relevant to the present invention is not limited to the above-described structure in which gas supply pipes are united to one pipe and connected to the lateral side of the manifold 209. For example, the first gas supply pipe 150, the second gas supply pipe 160, and the third gas supply pipe 170 may be individually connected to the lateral side of the manifold 209. In this case, gas supply nozzles may be connected to the downstream sides of the first gas supply pipe 150, the second gas supply pipe 160, and the third gas supply pipe 170, respectively. Although three gas supply systems are exemplified, the number of gas supply systems is not limited to three. For example, the number of gas supply systems may be two, four, or more according to substrate processing conditions.

(Gas Exhaust System)

As shown in FIG. 2, a gas exhaust pipe 231 is connected to the sidewall of the manifold 209 as a gas exhaust system configured to exhaust the inside atmosphere of the process chamber 201. At least two vacuum pumps are installed in series at the gas exhaust pipe 231. The vacuum pump disposed at the most upstream side of the gas exhaust pipe 231 is configured as a mechanical booster pump.

Specifically, as shown in FIG. 3, from the upstream side of the gas exhaust pipe 231, an automatic pressure control (APC) valve 232, a vacuum pump such as a first mechanical booster pump (root pump) 233, a second mechanical booster pump 234, and a dry pump 235 are sequentially installed in series.

For example, the first and second mechanical booster pumps 233 and 234 may have a structure in which two cocoon-shaped rotors are synchronously rotated in a casing by an axial-end driving gear. Gas sucked into the casing through an intake port installed at an end of the casing is confined between the casing and the two rotors and is moved according to the rotation of the rotors, and then the gas is discharged through an exhaust port installed at the other end of the casing. The rotors are configured to be rotated with a slight gap (for example, 0.1 mm to 0.3 mm) among the rotors and the casing. The inside of the casing is configured such that no lubricant is necessary. Therefore, oil-free vacuum exhaustion is possible.

If the dry pump 235 does not use pump oil that contaminates the inside of the process chamber 201, a mechanical vacuum pump such as a root pump, a claw pump, a screw pump, a turbo pump, and a scroll pump, or a physicochemical vacuum pump such as a sorption pump may be used as the dry pump 235.

The first mechanical booster pump 233, the second mechanical booster pump 234, and the dry pump 235 are installed in series at the gas exhaust pipe 231 such that a desired exhaust rate (for example, 60,000 slm) can be obtained. The total exhaust rate is determined mainly by the exhaust performance of the first mechanical booster pump 233. That is, the exhaust rate of the first mechanical booster pump 233 is the determining factor of the total exhaust rate, and the inside pressure of the process chamber 201 is mainly determined by the exhaust performance of the first mechanical booster pump 233.

At the gas exhaust pipe 231, a slow exhaust pipe 236 is installed to connect the upstream side of the APC valve 232 and the downstream side of the APC valve 232 (located between the first mechanical booster pump 233 and the APC valve 232). An on-off valve 237 is installed at the slow exhaust pipe 236. In addition, as a pressure detecting unit configured to detect the inside pressure of the process chamber 201, a pressure sensor (not shown) is installed in the gas exhaust pipe 231 at the upstream side of the APC valve 232. The installation position of the pressure sensor is not limited to the inside of the gas exhaust pipe 231. For example, the pressure sensor may be installed in the process chamber 201. A pressure control unit 304 is electrically connected to the pressure sensor and the APC valve 232. Based on pressure information detected using the pressure sensor, the pressure control unit 304 controls the opened degree of the APC valve 232 so that the inside pressure of the process chamber 201 can be adjusted to a desired level at a desired time.

The present invention is not limited to installation of three vacuum pumps: the first mechanical booster pump 233, the second mechanical booster pump 234, and the dry pump 235. For example, as shown in FIG. 4, the case where only the first mechanical booster pump 233 and the dry pump 235 (only two pumps) are installed (the second mechanical booster pump 234 is not used) may also be properly applied according to the present invention.

(Bypass Pipe)

As shown in FIG. 3, the substrate processing apparatus 101 relevant to the current embodiment includes: a first bypass pipe 155 connected between the first gas supply pipe 150 and the gas exhaust pipe 231 to bypass the process chamber 201, a second bypass pipe 165 connected between the second gas supply pipe 160 and the gas exhaust pipe 231 to bypass the process chamber 201, and a third bypass pipe 175 connected between the third gas supply pipe 170 and the gas exhaust pipe 231 to bypass the process chamber 201.

The upstream side of the first bypass pipe 155 is connected between the valve 151 and the MFC 152 of the first gas supply pipe 150, the upstream side of the second bypass pipe 165 is connected between the valve 161 and the MFC 162 of the second gas supply pipe 160, and the upstream side of the third bypass pipe 175 is connected between the valve 171 and the MFC 172 of the third gas supply pipe 170. The downstream sides of the first bypass pipe 155, the second bypass pipe 165, and the third bypass pipe 175 are connected to the gas exhaust pipe 231 between the first mechanical booster pump 233 and a vacuum pump located at the downstream side of the first mechanical booster pump 233 (that is, the second mechanical booster pump 234 in the case of FIG. 3, or the dry pump 235 in the case of FIG. 4). The structure of the downstream sides of the first bypass pipe 155, the second bypass pipe 165, and the third bypass pipe 175 is one of characteristic features of the substrate processing apparatus 101 relevant to the current embodiment.

Valves 156, 166, and 176 are installed at the first bypass pipe 155, the second bypass pipe 165, and the third bypass pipe 175, respectively. For example, the flowrates of gas flowing through the first bypass pipe 155, the second bypass pipe 165, and the third bypass pipe 175 may be 1 slm, respectively.

In the current embodiment, the number of bypass pipes corresponds to the number of process gas sources (that, three bypass pipes are installed). However, the present invention is not limited thereto. That is, in the present invention, bypass pipes may be installed for only some of the process gas sources. For example, a bypass pipe may be installed at one or both of the first gas supply pipe 150 and the second gas supply pipe 160, and no bypass pipe may be installed at the other gas supply pipes.

(Boat Elevator)

At the outer side of the sidewall of the loadlock chamber 140, the boat elevator 115 is installed. The boat elevator 115 includes a lower base plate 245, a guide shaft 264, a ball screw 244, an upper base plate 247, a lift motor 248, the lift base plate 252, and a bellows 265. The lower base plate 245 is horizontally fixed to the outer side of the sidewall of the loadlock chamber 140. The guide shaft 264 fitted to a lift stage 249, and the ball screw 244 thread-coupled to the lift stage 249 are vertically installed on the lower base plate 245. The upper base plate 247 is horizontally fixed to the upper ends of the guide shaft 264 and the ball screw 244. The ball screw 244 is configured to be rotated by the lift motor 248 installed on the upper base plate 247. In addition, the guide shaft 264 is configured to allow vertical movement of the lift stage 249 but suppress horizontal movement of the lift stage 249. The lift stage 249 can be moved upward and downward by rotating the ball screw 244.

A hollow lift shaft 250 is vertically fixed to the lift stage 249. The joint between the lift stage 249 and the lift shaft 250 is airtight. The lift shaft 250 is configured to be moved upward and downward together with the lift stage 249. The lower end part of the lift shaft 250 penetrates the top plate 251 of the loadlock chamber 140. A penetration hole is formed in the top plate 251, and the diameter of the hole is adjusted to be greater than the outer diameter of the lift shaft 250 so as to prevent the lift shaft 250 from making contact with the top plate 251. Between the loadlock chamber 140 and the lift stage 249, the bellows 265 made of a hollow flexible material is installed to cover the lift shaft 250. The joint between the lift stage 249 and the bellows 265, and the joint between the top plate 251 and the bellows 265 are airtight, such that the inside of the loadlock chamber 140 can be air-tightly maintained. The bellows 265 is sufficiently flexible for coping with the movement of the lift stage 249. The inner diameter of the bellows 265 is sufficiently larger than the outer diameter of the lift shaft 250 for prevent the bellows 265 making contact with the lift shaft 250.

The lower end of the lift shaft 250 protrudes to the inside of the loadlock chamber 140, and the lift base plate 252 is fixed to the lower end of the lift shaft 250. The joint between the lift shaft 250 and the lift base plate 252 is configured to be airtight. On the top surface of the lift base plate 252, the seal cap 219 is air-tightly installed with a seal member such as an O-ring being disposed therebetween. For example, the seal cap 219 is made of a metal such as stainless steel and has a disk shape. If the ball screw 244 is rotated by operating the lift motor 248, the lift stage 249, the lift shaft 250, the lift base plate 252, and the seal cap 219 can be lifted so as to load the boat 130 into the process furnace 202 (boat loading) and close the furnace port 261 (opening) of the process furnace 202 by using the seal cap 219. In addition, if the ball screw 244 is reversely rotated by operating the lift motor 248, the lift stage 249, the lift shaft 250, the lift base plate 252, and the seal cap 219 can be lowered so as to unload the boat 130 from the process chamber 201 (boat unloading). A driving control unit 305 is electrically connected to the lift motor 248. The driving control unit 305 controls the boat elevator 115 so that a desired operation of the boat elevator 115 can be carried out at a desired time.

On the bottom surface of the lift base plate 252, a driving unit cover 253 is air-tightly installed with a seal member such as an O-ring between disposed therebetween. A driving unit accommodating case 256 is constituted by the lift base plate 252 and the driving unit cover 253. The inside of the driving unit accommodating case 256 is isolated from the inside atmosphere of the loadlock chamber 140. Inside the driving unit accommodating case 256, a rotary mechanism 254 is installed. A power supply cable 258 is connected to the rotary mechanism 254. The power supply cable 258 extends from the upper end of the lift shaft 250 to the rotary mechanism 254 through the inside of the lift shaft 250 so as to supply power to the rotary mechanism 254. The upper end part of a rotation shaft 255 of the rotary mechanism 254 is configured to penetrate the seal cap 219 and support the bottom side of the boat 130 used as a substrate holding unit. By operating the rotary mechanism 254, wafers 200 held in the boat 130 can be rotated in the process chamber 201. The driving control unit 305 is electrically connected to the rotary mechanism 254. The driving control unit 305 controls the rotary mechanism 254 such that a desired operation of the rotary mechanism 254 can be performed at a desired time.

In addition, a cooling mechanism 257 is installed in the driving unit accommodating case 256 around the rotary mechanism 254. Cooling passages 259 are formed in the cooling mechanism 257 and the seal cap 219. Coolant pipes 260 are connected to the cooling passages 259 for supplying coolant to the cooling passages 259. The coolant pipes 260 extend from the upper end of the lift shaft 250 to the cooling passages 259 through the inside of the lift shaft 250 and are configured to supply coolant to the cooling passages 259.

(Boat)

The boat 130 used as a substrate holding unit is made of a heat-resistant material such as quartz (SiO₂) or silicon carbide (SiC) and is configured to hold a plurality of wafers 200 in a state where the wafers 200 are horizontally oriented and arranged in multiple stages with their centers being aligned. At the lower part of the boat 130, a plurality of disk-shaped insulation plates 216 functioning as insulating members and made of a heat-resistant material such as quartz (SiO₂) or silicon carbide (SiC) are horizontally oriented and arranged in multiple stages. Owing to the insulation plates 216, heat transfer from the heater 206 to the manifold 209 is difficult.

(Controller)

Furthermore, the substrate processing apparatus relevant to the current embodiment includes a controller 300 as a control unit. The controller 300 includes a main control unit 301, and the main control unit 301 includes a central processing unit (CPU), a memory, a storage device such as a hard disk drive (HDD), a manipulation unit, and an input/output unit. The main control unit 301 is electrically connected to the temperature control unit 302, a gas flowrate control unit 303, a pressure control unit 304, the driving control unit 305, the lift motor 248 of the boat elevator 115, and the rotary mechanism 254. The main control unit 301 is configured to control the overall operation of the substrate processing apparatus.

(4) Substrate Processing Process

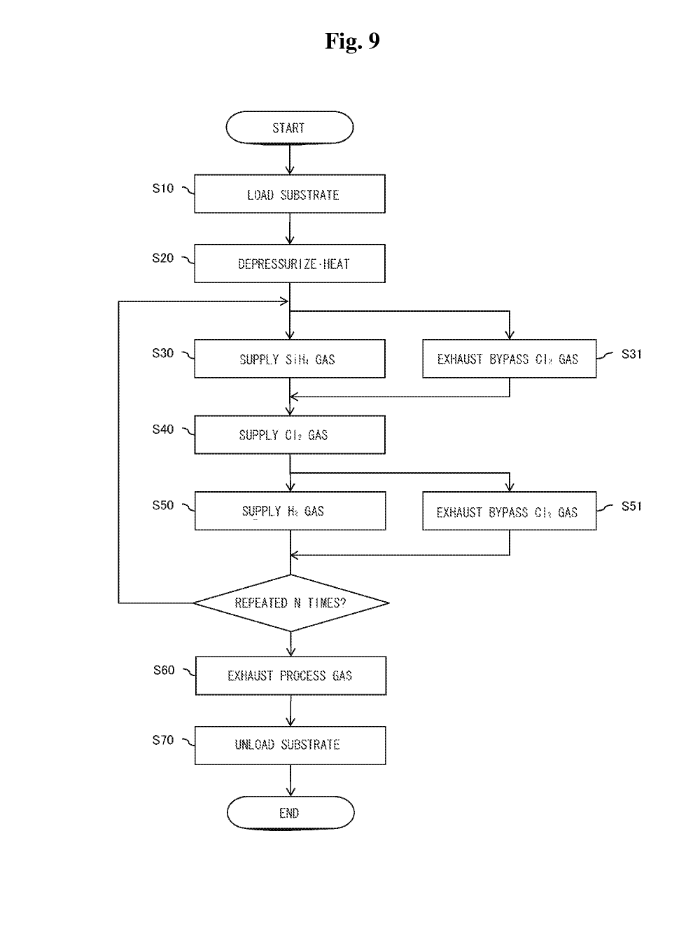

Hereinafter, as one of semiconductor device manufacturing processes relevant to the current embodiment, a substrate processing process for growing an Epi-Si film on a wafer 200 in cycles will be described with reference to FIG. 9. FIG. 9 is a flowchart for explaining a substrate processing process according to an embodiment of the present invention. Each part of the substrate processing apparatus 101 is controlled by the controller 300. In the first to third process gas supply sources 153, 163, and 173, flammable SiH₄ gas, Cl₂ gas which increases the susceptibility of substances to burn, and H₂ gas are respectively filled as first to third process gases, for example. In addition, silicon is exposed at least a surface part of a wafer 200 to be processed.

(Substrate Loading Operation S10)

First, the wafer transfer machine 112 charges a plurality of wafers 200 into the boat 130 that is located at a lower position. After a predetermined number of wafers 200 are charged into the boat 130, the lift motor 248 is operated so as to load the boat 130 holing the predetermined number of wafers 200 into the process chamber 201 (boat loading), and close the furnace port 261 (opening) of the process furnace 202 by using the seal cap 219.

(Depressurizing and Heating Operation S20)

Next, the inside of the process chamber 201 is vacuum-exhausted to a desired pressure (vacuum degree) by using the first mechanical booster pump 233, the second mechanical booster pump 234, and the dry pump 235. At this time, the valves 151, 161, 166, 171, and 176 are closed.

Thereafter, the inside pressure of the process chamber 201 is measured using the pressure sensor, and the APC valve 232 is feedback-controlled based on the measured pressure. In the current embodiment, the inside of the process chamber 201 may be depressurized to, for example, 40 Pa or lower. In addition, the inside of the gas exhaust pipe 231 between the first mechanical booster pump 233 and the second mechanical booster pump 234 may be depressurized to, for example, about 100 Pa. Since the downstream side of the valve 156 of the first bypass pipe 155, the downstream side of the valve 166 of the second bypass pipe 165, and the downstream side of the valve 176 of the third bypass pipe 175 are connected to the inside of the gas exhaust pipe 231 between the first mechanical booster pump 233 and the second mechanical booster pump 234, they may also be depressurized to, for example, about 100 Pa.

Since the first mechanical booster pump 233, the second mechanical booster pump 234, and the dry pump 235 that are installed at the gas exhaust pipe 231 do not use pump oil, the insides of the process chamber 201, the gas exhaust pipe 231, the first bypass pipe 155, the second bypass pipe 165, and the third bypass pipe 175 can be kept clean (oil-free).

In addition, the inside of the process chamber 201 is heated using the heater 206 so as to obtain a desired temperature distribution inside the process chamber 201. At this time, temperature information is detected using the temperature sensor, and power to the heater 206 is feedback-controlled based on the detected temperature information. Next, the boat 130 and the wafers 200 are rotated using the rotary mechanism 254.

(SiH₄ Gas Supply Operation S30)

Next, as a first process gas, SiH₄ gas is supplied from the first process gas supply source 153 (the first gas supply pipe 150) to the inside of the process chamber 201. Specifically, in a state where the valve 156 is closed and the valve 151 is opened, SiH₄ gas is supplied to the inside of the process chamber 201 while controlling the flowrate of the SiH₄ gas by using the MFC 152. The SiH₄ gas supplied to the inside of the process chamber 201 makes contact with the surfaces of the wafers 200 and is discharged from the process chamber 201 through the gas exhaust pipe 231. After the SiH₄ gas is supplied for a predetermined time, the valve 151 is closed to interrupt supply of the SiH₄ gas to the inside of the process chamber 201.

In the SiH₄ gas supply operation S30, preferably, the valve 176 is closed and the valve 171 is opened, and H₂ gas is supplied together with the SiH₄ gas to the inside of the process chamber 201 while controlling the flowrate of the H₂ gas by using the MFC 172. In this case, oxygen (O) that may exist at places such as the surfaces of the wafers 200 on which thin films to be formed can be removed by de-oxidation, and thus the concentration of oxygen in Epi-Si films can be lowered.

(Cl₂ Gas Bypass Exhaust Operation S31)

Until the SiH₄ gas supply operation S30 is completed, Cl₂ gas bypass exhaust operation S31 is concurrently performed, in which the flowrate of Cl₂ gas supplied from the second process gas supply source 163 (the second gas supply pipe 160) is stably maintained. In the Cl₂ gas bypass exhaust operation S31, Cl₂ gas is discharged to the gas exhaust pipe 231 through the second bypass pipe 165. That is, the valve 161 is closed, and the valve 166 is opened, so as to discharge Cl₂ gas to the gas exhaust pipe 231 through the second bypass pipe 165 without supplying the Cl₂ gas to the inside of the process chamber 201. This prevents an overshoot phenomenon in which the flowrate of Cl₂ gas supplied from the second process gas supply source 163 (the second gas supply pipe 160) is momentarily increased immediately after the start of Cl₂ gas supply.

As explained above, the inside of the gas exhaust pipe 231 between the first mechanical booster pump 233 and the second mechanical booster pump 234 is depressurized to, for example, about 100 Pa, and the inside of the process chamber 201 is depressurized to, for example, 40 Pa or lower. That is, the pressure inside the gas exhaust pipe 231 to which Cl₂ gas is discharged is greater than the pressure inside the process chamber 201. In spite of this pressure distribution, since the downstream side of the second bypass pipe 165 is connected between the first mechanical booster pump 233 and the second mechanical booster pump 234 in the current embodiment, back-diffusion (backflow) of Cl₂ gas to the inside of the process chamber 201 can be suppressed. That is, since the first mechanical booster pump 233 is installed at the upstream side of the joint point of the gas exhaust pipe 231 with the second bypass pipe 165, Cl₂ gas discharged from the second bypass pipe 165 to the gas exhaust pipe 231 can be prevented from diffusing (flowing) back to the upstream side of the gas exhaust pipe 231 (to the process chamber 201) instead of flowing to the downstream side of the gas exhaust pipe 231.

(Cl₂ Gas Supply Operation S40)

If the flowrate of Cl₂ gas supplied from the second process gas supply source 163 (the second gas supply pipe 160) is stabilized, Cl₂ gas is supplied to the inside of the process chamber 201 from the second gas supply pipe 160. In detail, the valve 166 is closed, and the valve 161 is opened, so as to supply Cl₂ gas to the inside of the process chamber 201 while controlling the flowrate of the Cl₂ gas by using the MFC 162. The Cl₂ gas supplied to the inside of the process chamber 201 makes contact with the surfaces of the wafers 200 and is discharged from the process chamber 201 through the gas exhaust pipe 231.

In the Cl₂ gas bypass exhaust operation S31, the destination (the inside of the second bypass pipe 165) of Cl₂ gas supplied from the second gas supply pipe 160 is depressurized to, for example, about 100 Pa, and in the Cl₂ gas supply operation S40, the destination (the inside of the process chamber 201) of Cl₂ gas supplied from the second gas supply pipe 160 is depressurized to, for example, 40 Pa or lower. That is, there is a slight pressure difference between the Cl₂ gas supply destinations of the Cl₂ gas bypass exhaust operation S31 and the Cl₂ gas supply operation S40. However, substrate processing quality or process yield is almost not affected by such a slight pressure difference. That is, although it is changed from the transition from the Cl₂ gas bypass exhaust operation S31 to the Cl₂ gas supply operation S40, the flowrate of Cl₂ gas is not significantly disturbed, and substrate processing quality or process yield is not significantly affected.

In the Cl₂ gas supply operation S40, preferably, the valve 176 is closed and the valve 171 is opened, and H₂ gas is supplied together with the Cl₂ gas to the inside of the process chamber 201 while controlling the flowrate of the H₂ gas by using the MFC 172. In this case, oxygen (O) that may exist at places such as the surfaces of the wafers 200 on which thin films to be formed can be removed by de-oxidation, and thus the concentration of oxygen in Epi-Si films can be lowered.

In this way, the SiH₄ gas supply operation S30 and the Cl₂ gas supply operation S40 are performed to supply SiH₄ gas and Cl₂ gas to the surfaces of the wafers 200, and thus, Epi-Si films can be selectively grown on exposed silicon surfaces of the wafers 200.

(Cl₂ Gas Bypass Exhaust Operation S51)

If the Cl₂ gas supply operation S40 is performed for a predetermined time (for example, 30 seconds), the valve 161 is closed, and the valve 166 is opened, so as to discharge Cl₂ gas to the gas exhaust pipe 231 through the second bypass pipe 165 without supplying the Cl₂ gas to the inside of the process chamber 201. In this case, since the downstream side of the second bypass pipe 165 is connected between the first mechanical booster pump 233 and the second mechanical booster pump 234, back-diffusion (backflow) of Cl₂ gas to the inside of the process chamber 201 can be suppressed.

In the Cl₂ gas bypass exhaust operation S51, the valve 161 can be closed in a state where the valve 166 is closed, so as to interrupt supply of Cl₂ gas to the inside of the process chamber 201 without bypassing Cl₂ gas to the second bypass pipe 165. In this case, by performing the Cl₂ gas bypass exhaust operation S31 again in a later operation, the flowrate of Cl₂ gas to the inside of the process chamber 201 can be stabilized.

(H₂ Gas Supply Operation S50)

In parallel with the Cl₂ gas bypass exhaust operation S51, H₂ gas supply operation S50 is performed. In detail, the valve 176 is closed, and the valve 171 is opened, so as to supply H₂ gas to the inside of the process chamber 201 while controlling the flowrate of the H₂ gas by using the MFC 172. By this operation, oxygen (O) that may exist at places such as the wafers 200 or Epi-Si films can be removed by de-oxidation, and thus the concentration of oxygen in the Epi-Si films can be lowered. After continuing the supply of H₂ gas, the valve 171 is closed to interrupt the supply of supply H₂ to the inside of the process chamber 201.

(Repetition of Operations)

The operations from the SiH₄ gas supply operation S30 to the Cl₂ gas bypass exhaust operation S51 are grouped as one cycle, and the cycle is repeated so as to selectively growing Epi-Si films on the exposed silicon surfaces of the wafers 200 to a desired thickness. The present invention is not limited to the above-described embodiment. For example, the SiH₄ gas supply operation S30, the Cl₂ gas supply operation S40, and the H₂ gas supply operation S50 may be simultaneously performed. In this case, the Cl₂ gas bypass exhaust operation S31 and the Cl₂ gas bypass exhaust operation S51 may also be performed before and after the Cl₂ gas supply operation S40, respectively. The H₂ gas supply operation S50 may not be performed. In this case, the SiH₄ gas supply operation S30, the Cl₂ gas bypass exhaust operation S31, the Cl₂ gas supply operation S40, and the Cl₂ gas bypass exhaust operation S51 may be grouped as one cycle, and this cycle may be repeated.

(Process Gas Exhaust Operation S60)

After the wafers 200 are processed by growing Epi-Si films on the wafers 200 to a desired thickness, process gases remaining in the process chamber 201 are exhaust through the gas exhaust pipe 231. At this time, the valves 151, 161, and 171 are closed. Inert gas such as N₂ gas may be supplied to the inside of the process chamber 201 through an inert gas supply line (not shown) so as to facilitate the exhaust of process gases from the inside of the process chamber 201. After the exhaust of the process gases, the opening of the APC valve 232 is controlled while supplying inert gas to the inside of the process chamber 201, so as to adjust the inside pressure of the process chamber 201 back to atmosphere pressure. Next, the operation of the rotary mechanism 254 is stopped. In a state where the APC valve 232 is closed, the on-off valve 237 can be opened so as to exhaust the inside of the process chamber 201 at a low speed.

(Substrate Unloading Operation S70)

Next, the seal cap 219 is moved downward by operating the lift motor 248. By this, the furnace port (opening) 261 of the process furnace 202 is opened, and at the same time, the boat 130 holding the wafers 200 on which films are formed is unloaded from the process chamber 201 (boat unloading). Thereafter, the processed wafers 200 are discharged from the boat 130 by using the wafer transfer machine 112 (wafer discharging). In this way, the substrate processing process relevant to the current embodiment is completed.

Process conditions for processing wafers 200, for example, conditions for forming Epi-Si films, may be as follows: process temperature is from 400° C. to 700° C., and process pressure is from 1 Pa to 200 Pa. In addition, in the SiH₄ gas supply operation S30, the flowrate of SiH₄ gas supply may be 100 sccm, and the flowrate of H₂ gas supply may be 1 slm. In the Cl₂ gas supply operation S40, the flowrate of Cl₂ gas supply may be 50 sccm, and the flowrate of H₂ gas supply may be 1 slm.

(Effects)

According to the current embodiment, one or more of the following effects (a) to (e) can be attained.

(a) According to the current embodiment, in parallel with the SiH₄ gas supply operation S30, the Cl₂ gas bypass exhaust operation S31 is performed. In the Cl₂ gas bypass exhaust operation S31, the valve 161 is closed, and the valve 166 is opened so as to discharge Cl₂ gas to the gas exhaust pipe 231 through the second bypass pipe 165 without supplying the Cl₂ gas to the inside of the process chamber 201. This prevents an overshoot phenomenon in which the flowrate of Cl₂ gas supplied from the second process gas supply source 163 (the second gas supply pipe 160) is momentarily increased immediately after the start of Cl₂ gas supply. Therefore, in the Cl₂ gas supply operation S40 that is performed after the Cl₂ gas bypass exhaust operation S31, the flowrate of Cl₂ gas supplied to the inside of the process chamber 201 can be stabilized, and thus, substrate processing quality can be improved to increase process yield.

(b) According to the current embodiment, the downstream side of the second bypass pipe 165 is connected between the first mechanical booster pump 233 and the second mechanical booster pump 234. Therefore, back-diffusion (backflow) of Cl₂ gas to the inside of the process chamber 201 can be suppressed. For example, in the Cl₂ gas bypass exhaust operation S31 or the Cl₂ gas bypass exhaust operation S51, the inside of the gas exhaust pipe 231 between the first mechanical booster pump 233 and the second mechanical booster pump 234 is depressurized to, for example, about 100 Pa, and the inside of the process chamber 201 is depressurized to, for example, 40 Pa or lower. That is, the pressure inside the gas exhaust pipe 231 to which Cl₂ gas is discharged is greater than the pressure inside the process chamber 201. In spite of this pressure distribution, since the first mechanical booster pump 233 is installed at the upstream side of the joint point of the gas exhaust pipe 231 with the second bypass pipe 165, Cl₂ gas discharged from the second bypass pipe 165 to the gas exhaust pipe 231 can be prevented from diffusing (flowing) back to the upstream side of the gas exhaust pipe 231 (to the process chamber 201) instead of flowing to the downstream side of the gas exhaust pipe 231. Therefore, substances such as contaminants remaining in the gas exhaust pipe 231 can be prevented from penetrating into the process chamber 201 together with Cl₂ gas, and thus substrate processing quality can be improved to increase process yield.

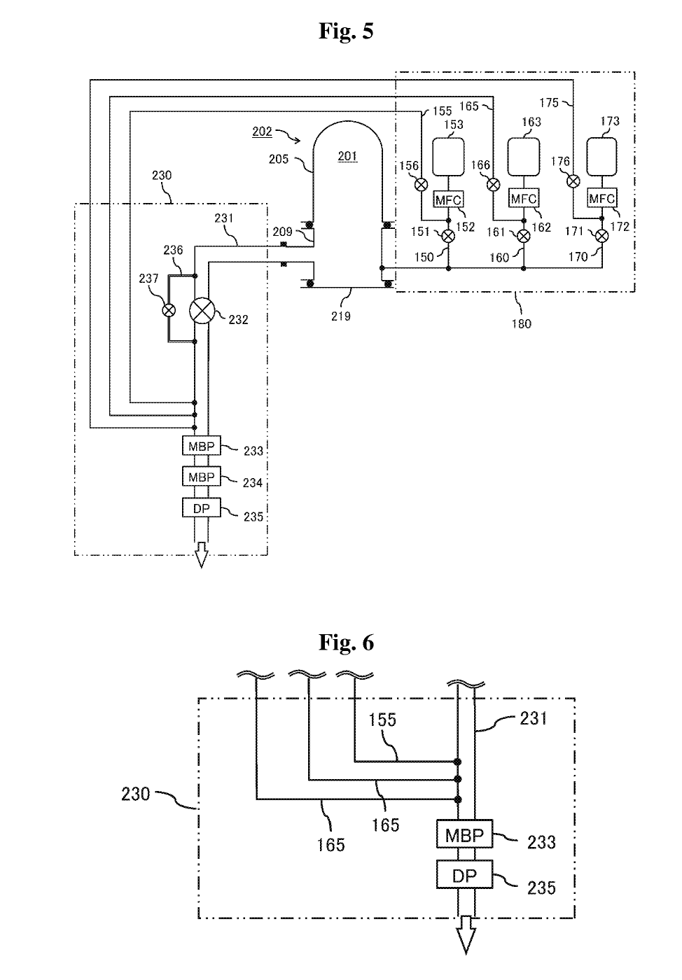

For reference, structures of a gas supply system, a bypass pipe, and a gas exhaust system of a substrate processing apparatus of the related art are schematically illustrated in FIG. 5 and FIG. 6. In the related-art substrate processing apparatus illustrated in FIG. 5, a first mechanical booster pump 233, a second mechanical booster pump 234, and a dry pump 235 (three vacuum pumps) are installed in series at a gas exhaust pipe 231. In the structure of the related-art substrate processing apparatus illustrating in FIG. 6, only the first mechanical booster pump 233 and the dry pump 235 (two vacuum pumps) are installed in series at the gas exhaust pipe 231. In any cases, the downstream sides of the first mechanical booster pump 233, the second mechanical booster pump 234, and the dry pump 235 are connected to the gas exhaust pipe 231 at the upstream side of the first mechanical booster pump 233. According to studies carried by the inventors et al, if Cl₂ gas is exhaust through a second bypass pipe 165 in the above-described structure, the Cl₂ gas exhausted to the gas exhaust pipe 231 can diffuse (flow) back to the inside of a process chamber 201. That is, in the substrate processing apparatus of the related art, unlike the current embodiment of the present invention, a vacuum pump (the first mechanical booster pump 233) is not installed at the upstream side of a joint point of the gas exhaust pipe 231 with the second bypass pipe 165. Therefore, if the pressure inside of the gas exhaust pipe 231 to which Cl₂ gas is discharged is greater than (or similar to) the pressure inside the process chamber 201, the Cl₂ gas discharged to the gas exhaust pipe 231 can diffuse (flow) back to the inside of the process chamber 201.

(c) According to the current embodiment, the downstream sides of the first bypass pipe 155, the second bypass pipe 165, and the third bypass pipe 175 are connected to the gas exhaust pipe 231 between the first mechanical booster pump 233 and a vacuum pump located at the downstream side of the first mechanical booster pump 233 (that is, the second mechanical booster pump 234 in the case of FIG. 3, or the dry pump 235 in the case of FIG. 4). Therefore, back-diffusion (backflow) of Cl₂ gas to the inside of the process chamber 201 can be prevented. That is, it may be unnecessary to install a dedicated vacuum pump at the downstream sides of the first bypass pipe 155, the second bypass pipe 165, and the third bypass pipe 175. Therefore, the substrate processing apparatus 101 can have a simple structure, and thus the manufacturing costs or installation footprint of the substrate processing apparatus 101 can be reduced.

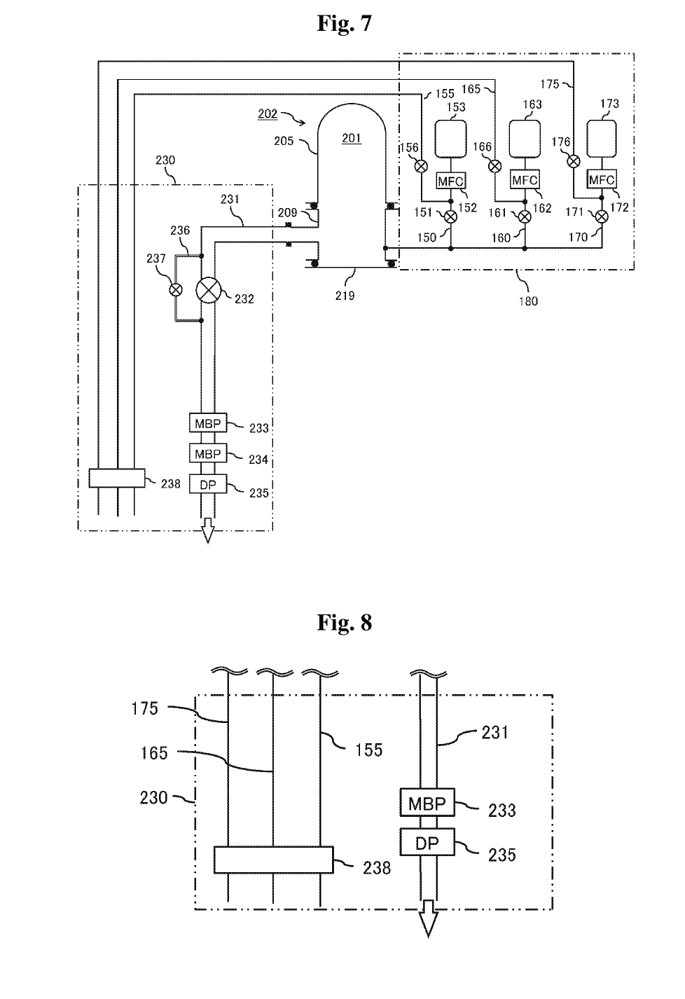

For reference, structures of a gas supply system, a bypass pipe, and a gas exhaust system of a substrate processing apparatus of the related art, in which a dedicated pump is installed at the bypass pipe, are illustrated in FIG. 7 and FIG. 8. In the related-art substrate processing apparatus illustrated in FIG. 7, a first mechanical booster pump 233, a second mechanical booster pump 234, and a dry pump 235 (three vacuum pumps) are installed in series at a gas exhaust pipe 231. In the structure of the related-art substrate processing apparatus illustrating in FIG. 8, only the first mechanical booster pump 233 and the dry pump 235 (two vacuum pumps) are installed in series at the gas exhaust pipe 231. In any cases, a first bypass pipe 155, a second bypass pipe 165, and a third bypass pipe 175 are not connected to the gas exhaust pipe 231, and a dedicated pump 238 is installed at the downstream sides of the first bypass pipe 155, the second bypass pipe 165, and the third bypass pipe 175. According to inspections by the inventors et al, if such a structure of the related art is employed, the structure of the substrate processing apparatus 101 may be complicated, and thus the manufacturing costs or installation footprint of the substrate processing apparatus 101 may be increased.

(d) According to the current embodiment, all of the first mechanical booster pump 233, the second mechanical booster pump 234, and the dry pump 235 installed at the gas exhaust pipe 231 are configured not to use pump oil, so that the insides of the process chamber 201, the gas exhaust pipe 231, the first bypass pipe 155, the second bypass pipe 165, and the third bypass pipe 175 can be kept clean (oil-free).

(e) According to the current embodiment, a mechanical booster pump (MBP) and a dry pump (DP) are installed at the gas exhaust pipe 231 as vacuum pumps instead of installing turbomolecular pumps (TMPs). A TMP is a kind of mechanical vacuum pump in which a rotor having metal turbine blades is rotated at a high speed to exhaust gas by flicking gas molecules (pushing and compressing gas molecules). Since compression to atmospheric pressure is difficult by using a TMP, it may be necessary to install a roughing vacuum pump at the downstream side of the TMP. According to inspections by the inventors et al, since it is necessary to supply process gas to the process chamber 201 at a large flowrate in a batch process (batch epitaxial film growing process) for processing a plurality of substrates at a time, rather than a TMP having a small effective operation range and unsuitable for exhausting process gas at a large flowrate, a combination of a mechanical booster pump and a dry pump may be preferable because the combination has a large effective operation range and suitable for exhausting process gas at a large flowrate. In addition, since a metal seal or a fastening bolt is necessary to fix a TMP to the gas exhaust pipe 231, a mechanical booster pump or a dry pump may be installed more easily. Generally, since a TMP has a smaller effective operation range than a mechanical booster pump, when a TMP is installed at the gas exhaust pipe 231, it is necessary to install the TMP at the most upstream side of the gas exhaust pipe 231 (a position closest to the process chamber 201) for optimize the exhaust efficiency of the TMP and suppressing back-diffusion (backflow) of process gas to the process chamber 201.

### Another Embodiment of the Present Invention

In the above-described embodiment, the valves 151 and 156, the valves 161 and 166, and the valves 171 and 176 may be configured as interlocks, respectively. For example, if one of the valves 151 and 156 is closed, the other may be automatically opened, and if one of the valves 151 and 156 is opened, the other may be automatically closed. Such an opening/closing operation is automatically controlled by the controller 300. In this case, the flowrate of process gas supply may be less distributed by valve opening/closing errors, and thus substrate processing quality can be improved to increase process yield.

In the above-described embodiment, to stabilize the flowrate of Cl₂ gas supply, Cl₂ gas is exhausted using the second bypass pipe 165. However, the present invention is not limited thereto. For example, like the case of Cl₂ gas, the flowrate of SiH₄ gas supply can also be stabilized by using the first bypass pipe 155. In addition, like the case of Cl₂ gas, the flowrate of H₂ gas supply can also be stabilized by using the third bypass pipe 175.

In the above-described embodiment, Epi-Si films are grown by supplying SiH₄ gas, Cl₂ gas, and H₂ gas to the inside of the process chamber 201. However, the present invention is not limited thereto. For example, silane-base gas such as Si₂H₆ other than SiH₄ gas may be filled in the first process gas supply source 153, and silane-based gas such as Si₂H₆, Cl₂ gas, and H₂ gas may be sequentially or simultaneously supplied to the inside of the process chamber 201 for growing Epi-Si films. This alternative case may also be properly applied according to the present invention.

In addition, the present invention can also be properly applied in the following case: silane-based gas such as SiH₄ gas or Si₂H₆ gas, germanium-based gas such as GeH₄ gas, and chlorine-based gas such as Cl₂ gas are filled in the first process gas supply source 153, the second process gas supply source 163, and the third process gas supply source 173, respectively; and these gases are sequentially or simultaneously supplied to the inside of the process chamber 201 for growing Epi-SiGe films. In this case, like the above-described embodiment, the first bypass pipe 155, the second bypass pipe 165, and the third bypass pipe 175 may be used to control the Si—Ge ratio, stabilize the flowrates of gases, and prevents back-diffusion (backflow) of gases to the inside of the process chamber 201. Furthermore, in the case of boron (B) doping, before supplying a boron-containing gas, the flowrate of the boron-contained gas can be stabilized by using a bypass pipe like in the above-described embodiment.

According to the substrate processing apparatus relevant to the present invention, process gas discharged from the bypass pipe to the gas exhaust system can be prevented from diffusing back to the inside of the process chamber without having to install a dedicated vacuum pump at the downstream side of the bypass pipe.

(Supplementary Note)

The present invention also includes the following exemplary embodiments.

(Supplementary Note 1)

According to a preferred embodiment of the present invention, there is provided a substrate processing apparatus including: a process chamber configured to accommodate a substrate; a gas supply system configured to supply a process gas from a process gas source to an inside of the process chamber for processing the substrate; a gas exhaust system configured to exhaust an inside atmosphere of the process chamber; two or more vacuum pumps installed in series at the gas exhaust system; and a bypass pipe connected between the gas supply system and the gas exhaust system for bypassing the process chamber, wherein the most upstream vacuum pump of the vacuum pumps installed at the gas exhaust system is a mechanical booster pump, and the bypass pipe is connected between the mechanical booster pump and the rest vacuum pumps located at a downstream side of the mechanical booster pump.

(Supplementary Note 2)

In the substrate processing apparatus of Supplementary Note 1, one of the vacuum pumps, which is located at a downstream side of a joint part of the gas exhaust system with the bypass pipe, may be a dry pump.

(Supplementary Note 3)

In the substrate processing apparatus of Supplementary Note 1, one of the vacuum pumps, which is located at a downstream side of a joint part of the gas exhaust system with the bypass pipe, may be a mechanical booster pump.

(Supplementary Note 4)

In the substrate processing apparatus of Supplementary Note 1, the rest vacuum pumps, which are located at a downstream side of a joint part of the gas exhaust system with the bypass pipe, may be sequentially a mechanical booster pump and a dry pump.

(Supplementary Note 5)

In the substrate processing apparatus of Supplementary Note 1, the process gas source may be plural in number, the bypass pipe may be plural in number, and the number of the bypass pipes may correspond to the number of the process gas sources, wherein each of the bypass pipes may be connected between the mechanical booster pump and the rest vacuum pumps located at the downstream side of the mechanical booster pump.

(Supplementary Note 6)

In the substrate processing apparatus of Supplementary Note 1, the process chamber is configured to accommodate a plurality of substrates.

(Supplementary Note 7)

According to another preferred embodiment of the present invention, there is provided a substrate processing apparatus including: a gas supply system configured to supply a process gas for processing a substrate; a process chamber configured to process the substrate; a gas exhaust system configured to exhaust gas supplied from the gas supply system; and a bypass pipe configured to directly connect the gas supply system and the gas exhaust system, wherein a mechanical booster pump and a dry pump are installed at the gas exhaust system, and the bypass pipe is connected between the mechanical booster pump and the dry pump.

(Supplementary Note 8)

According to another preferred embodiment of the present invention, there is provided a substrate processing apparatus including: a gas supply system configured to supply a process gas for processing a substrate; a process chamber configured to process the substrate; a gas exhaust system configured to exhaust gas supplied from the gas supply system; and a bypass pipe configured to directly connect the gas supply system and the gas exhaust system, wherein three vacuum pumps any of which is not a turbomolecular pump are installed at the gas exhaust system, and the bypass pipe is connected between the most upstream vacuum pump of the vacuum pumps and the rest vacuum pumps.

(Supplementary Note 9)

In the substrate processing apparatus of Supplementary Note 8, two of the three vacuum pumps are mechanical booster pumps, and the other one is a dry pump, wherein the most upstream side vacuum is one of the two mechanical booster pumps.

(Supplementary Note 10)

According to another preferred embodiment of the present invention, there is provided a method of manufacturing a semiconductor device by using a substrate processing apparatus including: a process chamber configured to accommodate a substrate; a gas supply system configured to supply a process gas from a process gas source to an inside of the process chamber for processing the substrate; a gas exhaust system configured to exhaust an inside atmosphere of the process chamber; two or more vacuum pumps installed in series at the gas exhaust system; and a bypass pipe connected between the gas supply system and the gas exhaust system for bypassing the process chamber, wherein the most upstream vacuum pump of the vacuum pumps installed at the gas exhaust system is a mechanical booster pump, and the bypass pipe is connected between the mechanical booster pump and the rest vacuum pumps located at a downstream side of the mechanical booster pump. The method includes: before processing a substrate, allowing process gas to flow to the bypass pipe to exhaust the process gas to the gas exhaust system, so as to stabilize the flowrate of the process gas supplied from the process gas source; supplying process gas from the process gas source to an inside of the process chamber, so as to process the substrate; and after processing the substrate, exhausting the process gas from the inside of the process chamber through the gas exhaust system.

What is claimed is:

1. A substrate processing apparatus comprising:
a process chamber configured to accommodate a substrate;
a gas supply system configured to supply a process gas from a process gas source to an inside of the process chamber for processing the substrate;
a gas exhaust system configured to exhaust an inside atmosphere of the process chamber;
two or more vacuum pumps installed in series at the gas exhaust system; and
a bypass pipe connected between the gas supply system and the gas exhaust system for bypassing the process chamber,
wherein the most upstream vacuum pump of the vacuum pumps installed at the gas exhaust system is a mechanical booster pump, and the bypass pipe is connected between the mechanical booster pump and the rest vacuum pumps located at a downstream side of the mechanical booster pump.

2. The substrate processing apparatus of claim 1, wherein one of the vacuum pumps, which is located at a downstream side of a joint part of the gas exhaust system with the bypass pipe, is a dry pump.

3. The substrate processing apparatus of claim 1, wherein one of the vacuum pumps, which is located at a downstream side of a joint part of the gas exhaust system with the bypass pipe, is a mechanical booster pump.

4. The substrate processing apparatus of claim 1, wherein the rest vacuum pumps, which are located at a downstream side of a joint part of the gas exhaust system with the bypass pipe, are sequentially a mechanical booster pump and a dry pump.

5. The substrate processing apparatus of claim 1, wherein the process gas source is plural in number, the bypass pipe is plural in number, and the number of the bypass pipes correspond to the number of the process gas sources,
wherein each of the bypass pipes is connected between the mechanical booster pump and the rest vacuum pumps located at the downstream side of the mechanical booster pump.
